(19) United States
(12) Patent Application Publication
(10) Pub. No.: US 2014/0063969 A1
(43) Pub. Date: Mar. 6, 2014

(54) FLASH MEMORY DEVICE AND OPERATING METHOD THEREOF

(71) Applicant: SK HYNIX INC., Gyeonggi-do (KR)

(72) Inventor: Chang-Won YANG, Gyeonggi-do (KR)

(73) Assignee: SK HYNIX INC., Gyeonggi-do (KR)

(21) Appl. No.: 13/720,358

(22) Filed: Dec. 19, 2012

(30) Foreign Application Priority Data
Aug. 31, 2012 (KR) 10-2012-0096600

(51) Int. Cl. G11C 16/26; G11C 16/06

(52) U.S. Cl. CPC G11C 16/26; G11C 16/06
USPC 365/185.21; 365/185.18; 365/185.25

(57) ABSTRACT

A semiconductor memory device includes a current sourcing unit configured to supply a given current to a source line when a read operation is performed, a memory cell string configured to store data and receive the given current from the source line, and a data sensing unit configured to sense the given current transferred from the memory cell string to a bit line and latch the sensed given current in a data form.

### CROSS-REFERENCE TO RELATED APPLICATION

The present application claims priority of Korean Patent Application No. 10-2012-0096600, filed on Aug. 31, 2012, which is incorporated herein by reference in its entirety.

### BACKGROUND

1. Field

Exemplary embodiments of the present invention relate to semiconductor design technology, and more particularly, to a flash memory device.

2. Description of the Related Art

In general, semiconductor memory devices are divided into volatile memory devices, such as Dynamic Random Access Memory (DRAM) and Static Random Access Memory (SRAM), and nonvolatile memory devices, such as Programmable Read Only Memory (PROM), Erasable PROM (EPROM), Electrically Erasable EPROM (EEPROM), and flash memory devices. The most significant characteristic for dividing semiconductor memory devices into volatile memory devices and nonvolatile memory device is whether data stored in a memory cell is retained or not after a specific time.

Whether the data is retained or not can be determined by a memory cell structure. That is, the volatile memory device does not retain the data stored in its memory cell after the specific time. In contrast, in a nonvolatile memory device, the data stored in its memory cell remains even after the specific time. Accordingly, in the case of the volatile memory device, an additional operation such as a refresh operation must be performed to retain data. In contrast, in the case of the nonvolatile memory device, such the additional operation does not need to be essentially performed. A nonvolatile memory device has been widely used as the storage medium for portable devices because this feature of the non-volatile memory device is suitable for a recent tendency toward low power consumption and high degree of integration.

Meanwhile, the flash memory device among the nonvolatile memory devices stores data in the memory cell through a program operation and an erase operation. Here, the program operation means an operation of accumulating electrons in the floating gate of a transistor that forms the memory cell, and the erase operation means an operation of discharging the accumulated electrons to a substrate. Through such operations, the flash memory device stores data of ‘0’ or ‘1’ in the memory cell.

FIG. 1 is a diagram illustrating part of a conventional flash memory device.

Referring to FIG. 1, the flash memory device includes a memory cell string 110 and a page buffer unit 120.

The memory cell string 110 includes a drain select transistor connected to a drain select line DSL and configured to perform a switching operation, a source select transistor connected to a source select line SSL and configured to perform a switching operation, and a plurality of memory cell transistors connected to corresponding word lines WL1 to WLN and configured to store data. The drain select transistor, the plurality of memory cell transistors and source select transistor are coupled in series. Furthermore, the page buffer unit 120 is configured to read data stored in a corresponding memory cell of the memory cell string 110 through a discharge operation from the direction of a bit line BL to the direction of a common source line SL.

The page buffer unit 120 has been precharged before a read operation. When a bit line select signal SEL_BL is activated, the electrons precharged in the page buffer unit 120 are transferred to the bit line BL. At this time, the common source line SL is connected to a ground voltage terminal VSS. Whether the precharged electrons transferred to the bit line BL will be discharged to the common source line SL or not is determined in response to data stored in the memory cells. In other words, when a corresponding memory cell of the memory cell string 110 has not been programmed, that is, when the threshold voltage of the corresponding memory cell is low, the electrons precharged in the page buffer unit 120 are discharged to the common source line SL through the bit line BL and the memory cell string 110. On the contrary, when the corresponding memory cell has been programmed, that is, when the threshold voltage of the corresponding memory cell is high, the electrons precharged in the page buffer unit 120 are not discharged to the common source line SL, because they are blocked by the corresponding memory cell of the memory cell string 110.

Meanwhile, the common source line SL is connected to a plurality of memory cell strings (not illustrated) in common in addition to the memory cell string 110 shown in FIG. 1. Accordingly, when such a read operation is performed, a large amount of current discharged from the plurality of memory cell strings flows through the common source line SL. From a viewpoint of each of the plurality of memory cell strings, a smooth discharge operation may not be achieved due to the large amount of current flowing through the common source line SL. Furthermore, this may result in an erroneous read operation or reduce the speed of the read operation.

### SUMMARY

Exemplary embodiments of the present invention are directed to provide a flash memory device capable of controlling an electric current that flows through a source line and a bit line when a read operation is performed.

In accordance with an embodiment of the present invention, a flash memory device may include a current sourcing unit configured to supply a given current to a source line when a read operation is performed; a memory cell string configured to store data and receive the given current from the source line; and a data sensing unit configured to sense the given current transferred from the memory cell string to a bit line and latch the sensed given current in a data form.

In accordance with another embodiment of the present invention, a flash memory device may include a current sourcing unit configured to supply a given data current to a source line when a read operation is performed; a memory cell string configured to store data and supplied with the data current through the source line; a current sinking unit configured to sink the data current by a given reference current; and a data sensing unit configured to sense the data current and latch the sensed data current in a data form.

In accordance with yet another embodiment of the present invention, an operating method of a flash memory device in which a memory cell string is coupled between a source line and a bit line may include supplying a given data current from the source line to the bit line via the memory cell string when a read operation is performed, sinking the data current by a given reference current; and sensing an amount of the data current and determining data stored in the memory cell string based on a result of the sensing.

A flash memory device in accordance with an embodiment of the present invention may transfer an electric current from the direction of a source line to a bit line when a read operation is performed and sense and output the electric current.

### BRIEF DESCRIPTION OF THE DRAWINGS

FIG. 1 is a diagram illustrating part of a conventional flash memory device.

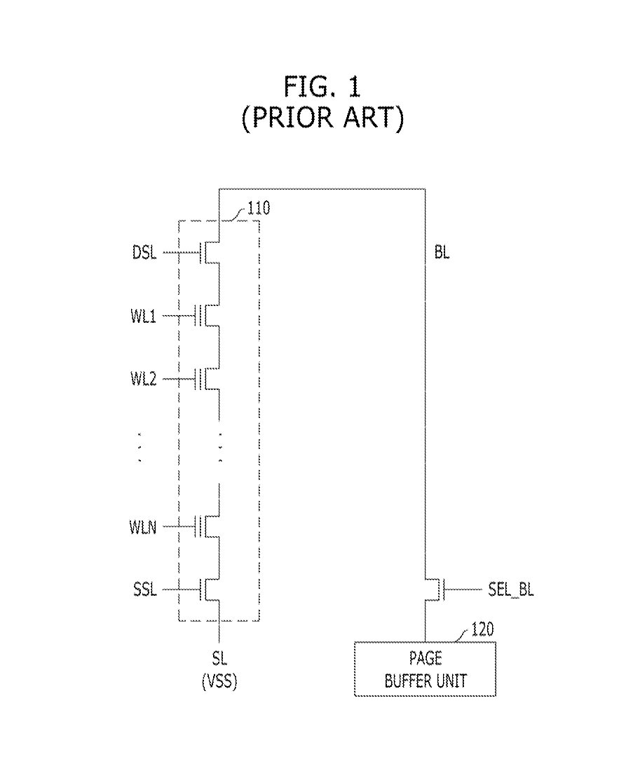

FIG. 2 is a diagram illustrating part of a flash memory device in accordance with an embodiment of the present invention.

FIG. 3 is a circuit diagram illustrating a flash memory device in accordance with an embodiment of the present invention.

FIG. 4 illustrates operating waveforms for illustrating an operation of the flash memory device shown in FIG. 3.

FIG. 5 is a circuit diagram illustrating another embodiment of the data sensing unit of the flash memory device shown in FIG. 3.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

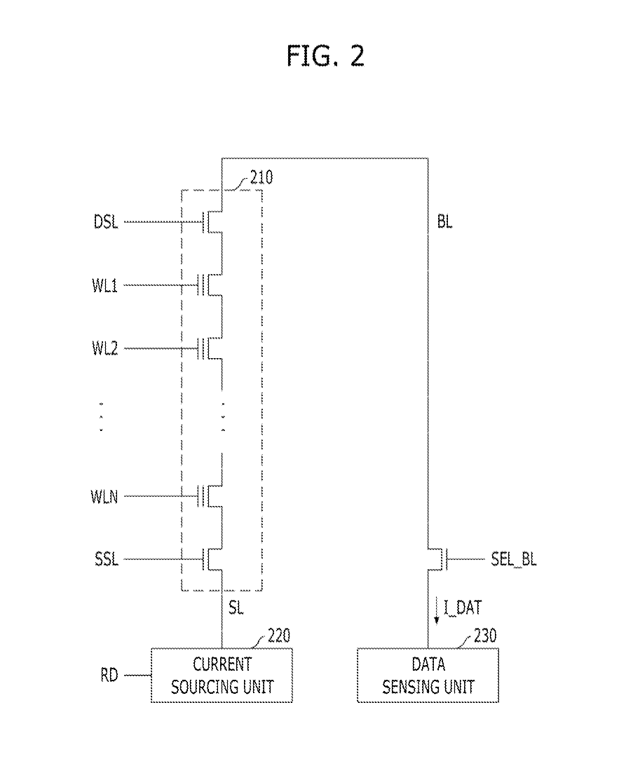

FIG. 2 is a diagram illustrating part of a flash memory device in accordance with an embodiment of the present invention.

Referring to FIG. 2, the flash memory device includes a memory cell string 210, a current sourcing unit 220, and a data sensing unit 230.

The memory cell string 210 is configured to store data. The memory cell string 210 includes a drain select transistor connected to a drain select line DSL and configured to perform a switching operation, a source select transistor connected to a source select line SSL and configured to perform a switching operation, and a plurality of memory cells connected to corresponding word lines WL1 to WLN and configured to store data. Here, the drain select line DSL and the source select line SSL are activated when a read operation is performed so that the memory cell string 210 and a source line SL are coupled and the memory cell string 210 and a bit line BL are coupled.

The current sourcing unit 220 is configured to supply a given current to the memory cell string 210 through the source line SL in response to a read command RD activated during the read operation. Here, the source line SL may also be connected to a plurality of memory cell strings (not illustrated) in addition to the memory cell string 210, or a plurality of the source lines SL may be connected to the plurality of memory cell strings, respectively.

The data sensing unit 230 configured to sense a data current I_DAT transferred through the bit line BL via the source line SL and the memory cell string 210 and to latch the sensed data.

Hereinafter, the read operation of the flash memory device is described briefly. It is assumed that a bit line select signal SEL_BL is activated, for convenience of description.

When the read operation is performed, the current sourcing unit 220 is activated and supplies a given current to the source line SL. Whether the supplied given current will be transferred to the bit line BL through the memory cell string 210 or not is determined in response to the data stored in the memory cell string 210. In other words, if a corresponding memory cell of the memory cell string 210 has a low threshold voltage, because it has not been programmed, the given current is transferred to the bit line BL through the memory cell string 210. On the contrary, if the corresponding memory cell has a high threshold voltage because it has been programmed, the given current is blocked by the memory cell string 210, and thus not transferred to the bit line BL. On the other hand, the data sensing unit 230 senses the data stored in the corresponding memory cell based on the amount of the data current I_DAT transferred through the bit line BL and latches the sensed data.

In the flash memory device in accordance with an embodiment of the present invention, when a read operation is performed, the data current I_DAT is transferred from the direction of the source line SL to the direction of the bit line BL, and the data stored in a corresponding memory cell is determined depending on whether the data current I_DAT has been transferred or not.

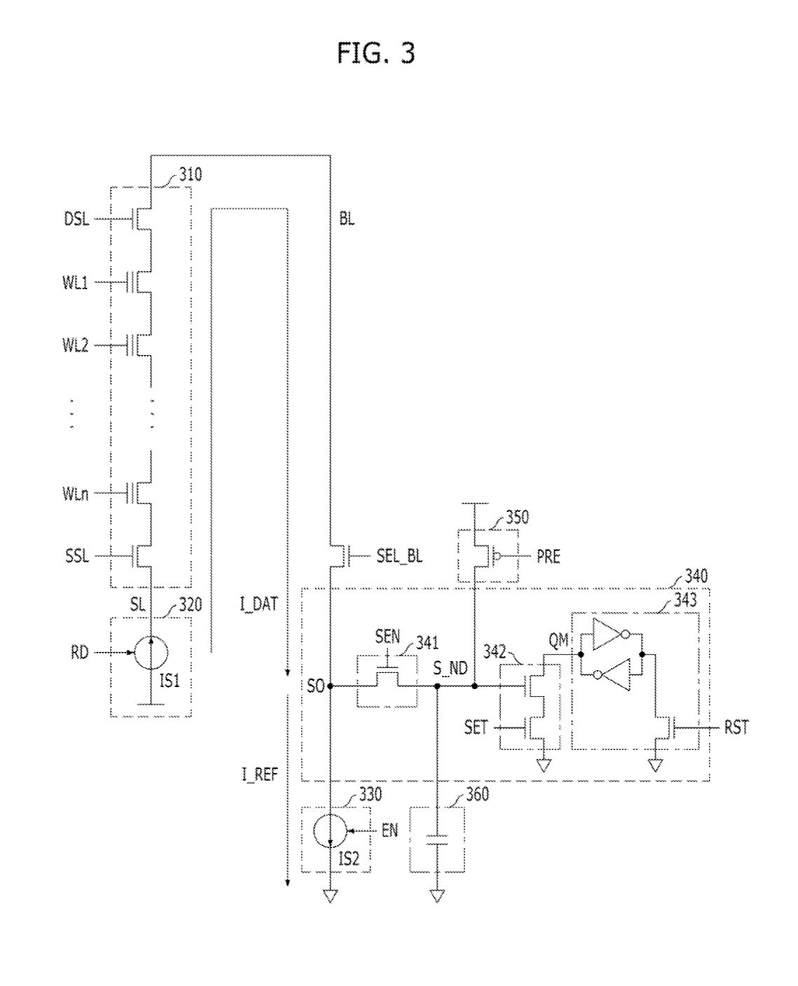

FIG. 3 is a circuit diagram illustrating a part of a flash memory device in accordance with another embodiment of the present invention.

Referring to FIG. 3, the flash memory device includes a memory cell string 310, a current sourcing unit 320, a current sinking unit 330, a data sensing unit 340, a precharging unit 350, and a voltage maintenance unit 360.

The memory cell string 310 is configured to store data and configured to receive a data current I_DAT from the current sourcing unit 320. Furthermore, the current sourcing unit 320 is configured to supply the data current I_DAT to a source line SL when a read operation is performed. The current sourcing unit 320 includes a first current source IS1 for generating the data current I_DAT in response to a read command RD activated during the read operation.

The current sinking unit 330 is configured to sink the data current I_DAT, transferred to a bit line BL through the memory cell string 310, by a given reference current I_REF. The current sinking unit 330 includes a second current source IS2 to sink the reference current I_REF in response to an enable signal EN. Here, the second current source IS2 may be designed in various ways. For example, the enable signal EN may be set as an analog signal or a digital signal, and the amount of the reference current I_REF may be controlled in response to the enable signal EN.

The data sensing unit 340 is configured to sense the data current I_DAT and latch the sensed data current in the form of data. The data sensing unit 340 includes a transfer unit 341, a sensing unit 342, and a latching unit 343. The transfer unit 341 transfers the data current I_DAT to a sense node S_ND from a common node SO when the read operation is performed. The sensing unit 342 senses the data current I_DAT transferred to the sense node S_ND. The latching unit 343 latches an output signal of the sensing unit 342 in the form of data.

The precharging unit 350 resets the sense node S_ND by performing a precharging operation on the sense node S_ND prior to the read operation. After the precharging operation, the voltage maintenance unit 360 maintains the voltage level of the sense node S_ND at a given voltage in order to secure a stable circuit operation.

The flash memory device in accordance with another embodiment of the present invention may discharge the data current I_DAT by the reference current I_REF using the current sinking unit 330. Here, the current sinking unit 330 may control the amount of the reference current I_REF in response to the enable signal EN, so that operation efficiency may be optimized when a read operation is performed. Furthermore, the operating speed of a circuit when a read operation is performed may be increased because the second current source IS2 of the current sinking unit 330 may be designed to have resistance lower than that of the first current source IS1 of the current sourcing unit 320.

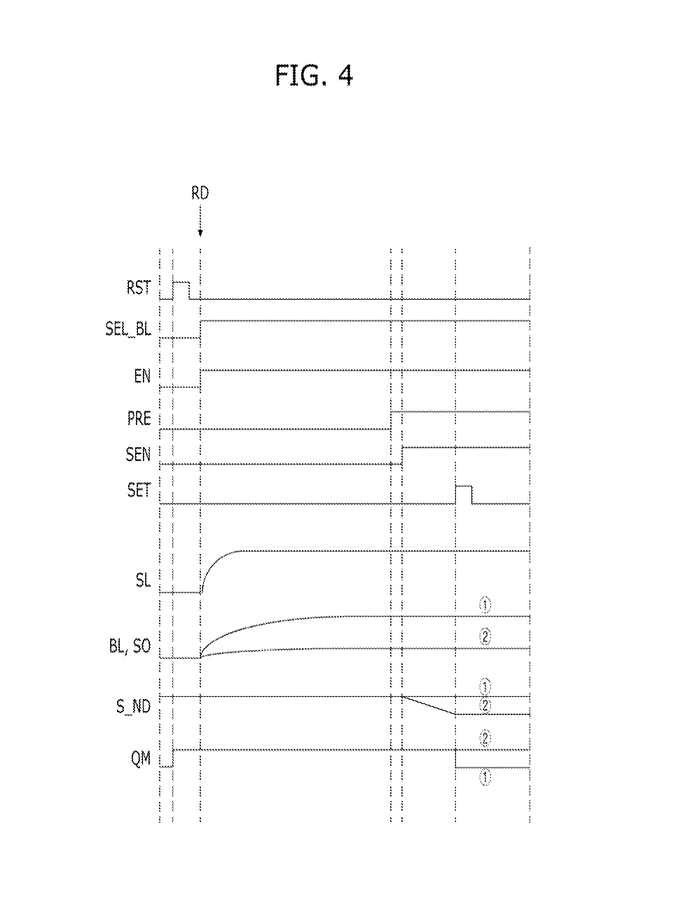

FIG. 4 shows operating waveforms for illustrating an operation of the flash memory device shown in FIG. 3. The read operation of the flash memory device is described briefly with reference to FIGS. 3 and 4.

First, when a reset signal RST shifts to logic ‘high, a data latching node QM becomes a logic level ‘H’. Next, when the read command RD is activated, a voltage level of the source line SL rises and thus the data current I_DAT is supplied from the direction of the source line SL to the direction of the memory cell string 310. The amount of the supplied data current I_DAT that is transferred to the bit line BL is determined in response to data stored in a corresponding memory cell. In other words, if the corresponding memory cell has a low threshold voltage because it has not been programmed (\textcircled{1}), a large amount of the data current I_DAT is transferred to the bit line BL. On the contrary, if the corresponding memory cell has a high threshold voltage because it has been programmed (\textcircled{2}), a small amount of the data current I_DAT is transferred to the bit line BL.

The flash memory device in accordance with an embodiment of the present invention may transfer the data current D_DAT from the direction of the source line SL to the direction of the bit line BL through the memory cell string 310 and sense the amount of current. The flash memory device in accordance with an embodiment of the present invention includes the current sinking unit 330 for controlling this data sense operation more precisely.

The current sinking unit 330 generates the reference current I_REF in response to the enable signal EN. Accordingly, there are two cases \textcircled{1} and \textcircled{2} depending on a correlation between the data current I_DAT and the reference current I_REF. The case \textcircled{1} corresponds to a case in which the amount of the data current I_DAT is great. In this case, although the reference current I_REF is discharged, the bit line BL has a high voltage level. The case \textcircled{2} corresponds to a case in which the amount of the data current I_DAT is small. In this case, the bit line BL has a low voltage level due to discharging by the reference current I_REF.

Meanwhile, the sense node S_ND maintains a precharging state in a section in which a precharging signal PRE has a logic level ‘L’. When the precharging signal PRE is deactivated in a logic level ‘H’ and a transfer signal SEN is activated, a voltage level of the sense node S_ND is determined by the amount of current of a common node SO. That is, in the case \textcircled{1} in which the amount of the data current I_DAT is great, the sense node S_ND maintains a precharging state. In the case \textcircled{2} in which the amount of the data current I_DAT is small, the voltage level of the sense node S_ND is lowered that much.

Furthermore, in the case \textcircled{1}, the sense node S_ND turns on the NMOS transistor of the sensing unit 342, and the data latching node QM shifts from a logic level ‘H’ to a logic level ‘L’ in response to a set signal SET. Furthermore, in the case \textcircled{2}, the sense node S_NS turns off the NMOS transistor of the sensing unit 342, and the latching node QM maintains a logic level ‘H’ although the set signal SET is activated.

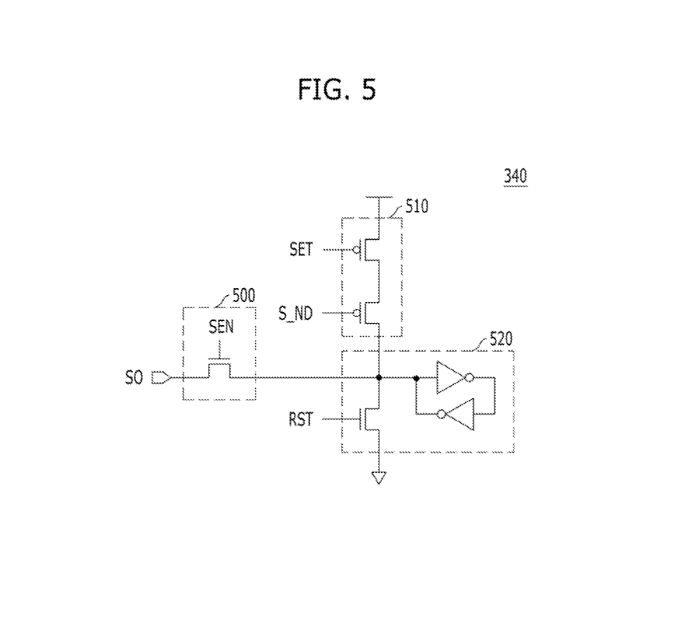

FIG. 5 is a circuit diagram illustrating another embodiment of the data sensing unit 340 of the flash memory device shown in FIG. 3.

Referring to FIG. 5, the data sensing unit 340 includes a transfer unit 500, a sensing unit 510 and a latching unit 520. The sensing unit 510 and the latching unit 520 of FIG. 5 correspond to the sensing unit 342 and the latching unit 343 of FIG. 3, respectively, and thus, a description of the operations of the sensing unit 510 and the latching unit 520 is omitted.

As described above, the flash memory device in accordance with an embodiment of the present invention may transfer the data current I_DAT from the direction of the source line SL to the direction of the bit line BL when a read operation is performed and determine data stored in a corresponding memory cell based on amounts of the data current I_DAT and the reference current I_REF. Furthermore, the second current source IS2 may be designed to have very low resistance, and thus, the operating speed of a circuit may be increased when a read operation is performed.

In addition, the positions and types of the logic gates and the transistors illustrated in the above-described embodiments may be embodied differently depending on the polarity of an input signal.

As described above, a read operation is performed by sensing an electric current that flows from a source line to a bit line. Accordingly, there is an advantage in that the time taken for the read operation may be minimized.

While the present invention has been described with respect to the specific embodiments, it will be apparent to those skilled in the art that various changes and modifications may be made without departing from the spirit and scope of the invention as defined in the following claims.

What is claimed is:

1. A flash memory device comprising:
a current sourcing unit configured to supply a given current to a source line when a read operation is performed;
a memory cell string configured to store data and receive the given current from the source line; and
a data sensing unit configured to sense the given current transferred from the memory cell string to a bit line and latch the sensed given current in a data form.

2. The flash memory device of claim 1, wherein the memory cell string comprises:
a plurality of memory cells configured to be coupled in series to store data;
a source select transistor configured to couple the memory cells to the source line when the read operation is performed; and
a drain select transistor configured to couple the memory cells to the bit line when the read operation is performed.

3. The flash memory device of claim 1, wherein a plurality of the memory cell strings are provided, and the source line is coupled to the plurality of the memory cell strings in common.

4. The flash memory device of claim 1, wherein a plurality of the memory cell strings and a plurality of source lines are provided, and the plurality of the source lines are coupled to the plurality of the memory cell strings, respectively.

5. A flash memory device comprising:
a current sourcing unit configured to supply a given data current to a source line when a read operation is performed;
a memory cell string configured to store data and supplied with the data current through the source line;
a current sinking unit configured to sink the data current by a given reference current; and
a data sensing unit configured to sense the data current and latch the sensed data current in a data form.

6. The flash memory device of claim 5, wherein a plurality of the memory cell strings are provided, and the source line is coupled to the plurality of the memory cell strings.

7. The flash memory device of claim 5, wherein a plurality of the memory cell strings and a plurality of the source lines are provided, and the plurality of the source lines are coupled to the plurality of the memory cell strings, respectively.

8. The flash memory device of claim 5, wherein the data sensing unit comprises:
a transfer unit configured to transfer the data current to a sense node when the read operation is performed;
a sensing unit configured to sense the data current transferred to the sense node; and
a latching unit configured to latch an output signal of the sensing unit.

9. The flash memory device of claim 8, further comprising:
a precharging unit configured to precharge the sense node; and
a voltage maintenance unit configured to maintain the sense node at a given voltage.

10. The flash memory device of claim 5, wherein the current sinking unit has a resistance value smaller than the current sourcing unit.

11. An operating method of a flash memory device in which a memory cell string is coupled between a source line and a bit line, the operating method comprising:
supplying a given data current from the source line to the bit line via the memory cell string when a read operation is performed;
sinking the data current by a given reference current; and
sensing an amount of the data current and determining data stored in the memory cell string based on a result of the sensing.

12. The operating method of claim 11, wherein an amount of the data current is controlled in response to the data stored in the memory cell string.

13. The operating method of claim 11, wherein the determining of data stored in the memory cell string based on a result of the sensing comprises:
transferring the data current to a sense node; and
determining a voltage level of the sense node and storing the determined voltage level in a data form.

14. The operating method of claim 11, wherein the determining of data stored in the memory cell string based on a result of the sensing comprises an operation of calculating the data current and the reference current.
